(19) United States
(12) Patent Application Publication
(10) Pub. No.: US 2004/0159850 A1
(43) Pub. Date: Aug. 19, 2004

(54) Semiconductor light-emitting device, manufacturing method thereof, and electronic image pickup device

(75) Inventor: Yasuji Takenaka, Nara-Shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-Shi (JP)

(21) Appl. No.: 10/782,331

(22) Filed: Feb. 18, 2004

(30) Foreign Application Priority Data
Feb. 18, 2003 (JP) 2003-039609
Dec. 17, 2003 (JP) 2003-419433

(51) Int. Cl. H01L 33/00

(52) U.S. Cl. 257/98

(57) ABSTRACT

A semiconductor light-emitting device includes a lead frame having a main surface, a LED chip, an epoxy resin provided to completely cover the LED chip, and a resin portion provided to surround the LED chip. The epoxy resin includes a top surface. The resin portion includes a top surface at a position where a distance from the main surface is greater than a distance from the main surface to the top surface, and an inner wall provided on the side where the LED chip is located and extending in a direction away from the main surface to reach the top surface. Thus, the semiconductor light-emitting device excellent in heat radiation and permitting appropriate control of directivity of the light, a manufacturing method thereof, and an electronic image pickup device are provided.

This nonprovisional application is based on Japanese Patent Applications Nos. 2003-039609 and 2003-419433 filed with the Japan Patent Office on Feb. 18, 2003 and Dec. 17, 2003, the entire contents of which are hereby incorporated by reference.

### BACKGROUND OF THE INVENTION

1. Field of the Invention

The present invention generally relates to a semiconductor light-emitting device, a manufacturing method thereof, and an electronic image pickup device. More particularly, the present invention relates to a semiconductor light-emitting device employing a semiconductor light-emitting element such as a light-emitting diode (LED), a manufacturing method of the semiconductor light-emitting device, and an electronic image pickup device.

2. Description of the Background Art

FIG. 16 is a cross sectional view illustrating a typical structure of a conventional semiconductor light-emitting device. Referring to FIG. 16, the semiconductor light-emitting device includes a lead frame 101 having a main surface 101a. Lead frame 101 is formed into a prescribed pattern, and a slit-shaped groove 101m is formed at main surface 101a. Lead frame 101 is folded such that terminal portions 101n are each formed at a distance from main surface 101a. Terminal portions 101n are connected, e.g., to a board on which the semiconductor light-emitting device is mounted.

A resin portion 103 is provided around lead frame 101 by insert molding, for example. Resin portion 103 defines a depression 103m on main surface 101a. A LED chip 104 is mounted on main surface 101a, via a silver (Ag) paste 107, to be located inside depression 103m. An electrode formed on the top surface of LED chip 104 is connected to main surface 101a of lead frame 101 via bonding wire 105.

An epoxy resin 106 is provided on main surface 101a to cover LED chip 104 and bonding wire 105 and to completely fill in depression 103m.

A manufacturing method of the semiconductor light-emitting device in FIG. 16 is now described. Firstly, plate-shaped lead frame 101 is processed into a prescribed pattern. Lead frame 101, plated with silver (Ag), is insert-molded in resin portion 103. Thereafter, LED chip 104 is mounted on main surface 101a via silver paste 107. LED chip 104 and main surface 101a are electrically connected via bonding wire 105.

LED chip 104 and bonding-wire 105 are sealed with epoxy resin 106. Since lead frame 101 is plated with silver, rust may occur, which would hinder soldering. As such, lead frame 101 has its exterior plated with solder, for example. Lastly, with an unnecessary portion cut away, lead frame 101 is bent to a prescribed shape to form terminal portions 101n.

Such conventional semiconductor light-emitting devices are disclosed, e.g., in Japanese Patent Laying-Open No. 7-235696 and Japanese Patent Laying-Open No. 2002-141558.

When an attempt is made to increase luminance of the semiconductor light-emitting device, however, the device as shown in FIG. 16 poses the following problems.

Resin portion 103 not only keeps the shape of lead frame 101 formed into the prescribed pattern, but also controls directivity of light by reflecting the light emitted from LED chip 104 with the sidewall of depression 103m. However, the traveling direction of the light emitted from LED chip 104 changes by refraction as it exits from the top surface side of epoxy resin 106. As such, it is difficult, with the conventional techniques, to adequately control the directivity of the light to increase the luminance of the semiconductor light-emitting device.

Further, in order to prevent occurrence of short-circuiting due to unintentional contact between the board on which the semiconductor light-emitting device is mounted and lead frame 101, lead frame 101 is folded to form terminal portions 101n. However, since the height of the semiconductor light-emitting device as a product is restricted, a sufficient height of resin portion 103 cannot be guaranteed with such lead frame 101 having the folded structure. This also hinders the increase in luminance of the semiconductor light-emitting device with the conventional techniques.

When an attempt is made to improve heat radiation of the semiconductor light-emitting device, the device as shown in FIG. 16 poses problems.

Firstly, the necessity to improve the heat radiation of the semiconductor light-emitting device is explained briefly. Heat is generated when LED chip 104 mounted emits light. The amount of heat generated increases with an increase of the current passing through LED chip 104. Generally, as the temperature of LED chip 104 increases, emission efficiency of LED chip 104 decreases, leading to considerable degradation of light. That is, even if a large amount of current is passed through LED chip 104, bright light cannot be obtained efficiently, and the lifetime of LED chip 104 may also be shortened. As such, it is necessary to effectively release the heat generated from LED chip 104 to the outside.

The following are conceivable ways to improve the heat radiation of the semiconductor light-emitting device:

(a) To increase the thickness of lead frame 101;

(b) To reduce the distance from LED chip 104 to terminal portions 101n; and

(c) To use a material having high heat conductivity to form lead frame 101.

With the conventional techniques, however, it is necessary to bend lead frame 101 in the process of manufacturing the semiconductor light-emitting device, and therefore, the thickness of lead frame 101 can be increased only to a certain extent.

Further, lead frame 101 is formed into a prescribed pattern by punching the plate material with a mold. If lead frame 101 is increased in thickness, the mold also needs to be increased in thickness to ensure the strength of the mold when punching the plate. This increases the width of the portion of the plate to be punched out by the mold, i.e., the width of slit-shaped groove 101m. In such a case, it is difficult to secure an adequate region on main surface 1a for bonding. Further, the decrease in surface area of lead frame 101 will adversely degrade the efficiency of heat radiation. As such, the above-described option (a) for improving the head radiation of the semiconductor light-emitting device cannot be adopted.

The distance from LED chip 104 mounted on main surface 101a to terminal portions 101n can be decreased only to a certain extent, because of the structure of lead frame 101 having terminal portions 101n each formed at a distance from main surface 101a by folding the frame. As such, the above-described option (b) for improving the heat radiation of the semiconductor light-emitting device cannot be adopted either.

Further, for the same reason associated with the structure of lead frame 101, it is necessary to select a material excellent in bendability as the material for lead frame 101. This means that a material simply having good heat conductivity cannot be employed for lead frame 101. As such, the above-described option (c) for improving the heat radiation of the semiconductor light-emitting device cannot be adopted either.

### SUMMARY OF THE INVENTION

The present invention has been made to solve the above-described problems, and its object is to provide a semiconductor light-emitting device excellent in heat radiation and capable of controlling directivity of light appropriately, a manufacturing method thereof, and an electronic image pickup device.

A semiconductor light-emitting device according to the present invention includes: a lead frame having a main surface in which a first region and a second region extending along the periphery of the first region (10) are defined; a semiconductor light-emitting element provided at the first region; a first resin member provided at the first region to completely cover the semiconductor light-emitting element; and a second resin member provided at the second region to surround the semiconductor light-emitting element. The first resin member has a first reflectivity with respect to light emitted from the semiconductor light-emitting element, and the second resin member has a second reflectivity greater than the first reflectivity with respect to the light emitted from the semiconductor light-emitting element. The first resin member includes a first top surface. The second resin member includes a second top surface that is provided at a position where a distance from the main surface is greater than a distance from the main surface to the first top surface, and an inner wall that is provided on a side where the semiconductor light-emitting element is located and extends in a direction away from the main surface to reach the second top surface.

According to the semiconductor light-emitting device configured as above, the light emitted from the semiconductor light-emitting element transmits the first resin member having a relatively small reflectivity, and is emitted to the outside from the first top surface of the first resin member. In the present invention, the second resin member has the second top surface provided at a higher level than the first top surface. As such, the inner wall of the second resin member exists even above the first top surface, and therefore, the light emitted from the first top surface can be reflected with the inner wall of the second resin member having a relatively great reflectivity. Accordingly, it is possible to appropriately control the directivity of the light, and to obtain high-luminance light from the semiconductor light-emitting device. In addition, since the first top surface is provided at a lower level than the second top surface, attenuation of the light emitted from the semiconductor light-emitting element when it transmits the first resin member can be suppressed. Accordingly, it is possible to obtain light of still higher luminance from the semiconductor light-emitting device.

Preferably, the semiconductor light-emitting device further includes a metallic wire having one end connected to the semiconductor light-emitting element and another end connected to the main surface, and the first resin member is provided to completely cover the metallic wire. According to the semiconductor light-emitting device thus configured, the first resin member not only has the above-described effects, but also protects the metallic wire provided as the interconnection of the semiconductor light-emitting element.

Still preferably, the one end of the metallic wire is formed in a line shape, and the anther end of the metallic wire is formed in a ball shape. According to the semiconductor light-emitting device thus configured, the metallic wire is connected to a prescribed position by ball bonding the another end of the metallic wire to the main surface of the lead frame, and then wedge bonding the one end of the metallic wire to the semiconductor light-emitting element. As such, the one end of the metallic wire connected to the semiconductor light-emitting element forms a loop of low profile. Accordingly, it is possible to provide the first top surface at a still lower level with respect to the second top surface.

Still preferably, the one end of the metallic wire is provided with a ball-shaped metal to sandwich the metallic wire between the ball-shaped metal and the semiconductor light-emitting element. According to the semiconductor light-emitting device thus configured, the connection between the one end of the metallic wire and the semiconductor light-emitting element can further be ensured. This improves reliability of the semiconductor light-emitting device.

Preferably, the semiconductor light-emitting device includes three such semiconductor light-emitting elements emitting light of red, blue and green, respectively, and three such lead frames spaced apart from each other and provided with the respective semiconductor light-emitting elements. The lead frames extend in different directions from each other. According to the semiconductor light-emitting device thus configured, heat generated at the semiconductor light-emitting elements by emitting light is transmitted to the lead frames. Since the lead frames extend in different directions, the directions in which the heat is transmitted can be dispersed. Accordingly, it is possible to efficiently release the heat generated by the semiconductor light-emitting elements from the lead frames.

Still preferably, areas of the main surfaces of the lead frames provided with the semiconductor light-emitting elements emitting the light of blue and green, respectively, are each greater than an area of the main surface of the lead frame provided with the semiconductor light-emitting element emitting the light of red. The semiconductor light-emitting elements emitting light of blue and green each generate the greater amount of heat than the semiconductor light-emitting element emitting light of red. Therefore, according to the semiconductor light-emitting device configured as above, the heat generated by the semiconductor light-emitting elements emitting light of the different colors can be released uniformly via the lead frames.

Still preferably, the lead frame includes portions separated by a slit-shaped groove, and the portions are formed thinner than the other portion of the lead frame. According to the semiconductor light-emitting device thus configured, the lead frame can be processed to have the slit-shaped groove of a small width separating the relevant portions. By comparison, the other portion of the lead frame can be made relatively thick, so that the efficiency in heat radiation by the lead frame can be improved.

Still preferably, the lead frame is formed in a plate shape extending in one plane. According to the semiconductor light-emitting device thus configured, the height of the lead frame is restricted low, and thus, the distance from the main surface to the second top surface can be increased for provision of the second resin member. This further facilitates control of the directivity of the light emitted from the semiconductor light-emitting element. Further, the material for the lead frame can be selected without taking bendability into consideration. Accordingly, it is possible to form the lead frame with a material having good heat conductivity, to thereby improve the effect of heat radiation by the lead frame.

Still preferably, the lead frame includes a first depression that is formed at an opposite surface with respect to the main surface and filled with a resin. Terminal portions to be electrically connected to a mounting board are provided on the opposite surface, on respective sides of the first depression. According to the semiconductor light-emitting device thus configured, short-circuiting that would occur when the mounting board comes into contact with an unexpected portion of the lead frame can be prevented. It is thus possible to appropriately achieve the electrical connection between the lead frame and the mounting board via the terminal portions.

Still preferably, the lead frame includes a second depression formed at the first region, and the semiconductor light-emitting element is provided in the second depression. According to the semiconductor light-emitting device thus configured, the light emitted from the semiconductor light-emitting element is reflected by the sidewall of the lead frame defining the second depression. This further facilitates control of the directivity of the light emitted from the semiconductor light-emitting element.

Still preferably, the lead frame is formed of a metal having a heat conductivity of not lower than 300 W/mK and not greater than 400 W/mK. When the heat conductivity is lower than 300 W/mK, the effect of heat radiation by the lead frame cannot be enjoyed satisfactorily. If the heat conductivity is greater than 400 W/mK, the heat generated upon mounting of the lead frame may be transmitted to the semiconductor light-emitting element, leading to degradation in reliability of the semiconductor light-emitting element. According to the semiconductor light-emitting device having the lead frame formed of the metal having the prescribed heat conductivity, heat radiation by the lead frame can be ensured without the degradation in reliability of the semiconductor light-emitting element.

Still preferably, the second resin member is formed such that an area of the shape defined by the inner wall in a plane parallel to the main surface increases with an increase of a distance from the main surface. According to the semiconductor light-emitting device thus configured, the light can be emitted frontward efficiently. As such, it is possible to obtain the light emitted from the semiconductor light-emitting element with high luminance.

Still preferably, the shape defined by the inner wall in a plane parallel to the main surface is one of circle, ellipse and polygon. According to the semiconductor light-emitting device thus configured, in addition to the effect that the light can be emitted frontward efficiently, the directivity of the light can be controlled with ease.

Still preferably, the lead frame includes a lead terminal projecting from the periphery of the main surface and extending in a prescribed direction. The lead terminal has a tip end portion having an end surface formed at a tip end extending in the prescribed direction, and a base portion located between the periphery of the main surface and the tip end portion. The lead terminal is formed such that an area of the end surface is smaller than a cross sectional area of the base portion in a plane parallel to the end surface. The end surface formed at the tip end portion corresponds to a cut surface formed by a prescribed cutting tool.

A manufacturing method of the semiconductor light-emitting device according to the present invention includes: the step of preparing a lead frame base member having a plurality of semiconductor light-emitting devices formed thereon; and the step of cutting the plurality of semiconductor light-emitting devices out of the lead frame base member by cutting the lead frame base member at the tip end portions.

According to the semiconductor light-emitting device and the manufacturing method thereof configured as above, the end surface formed at the tip end portion of the lead terminal corresponds to the cut surface formed when the semiconductor light-emitting device is cut out of the lead frame base member. Thus, the metal as the base material of the lead frame is exposed at the end surface, which may be affected by oxidization or the like, leading to degradation in wettability with respect to solder. In the present invention, the lead terminal is formed such that the end surface has a relatively small area, so that wettability of the lead terminal with respect to the solder upon mounting of the semiconductor light-emitting device can be ensured. In addition, since the tip end portion can be cut out with a smaller force in the step of cutting the semiconductor light-emitting device out of the lead frame base member, the manufacturing process of the semiconductor light-emitting device can be facilitated.

Still preferably, the lead terminal has a first width at the base portion and a second width smaller than the first width at the tip end portion. Here, the first and second widths correspond to their lengths, in planes parallel to the main surface, in a direction orthogonal to a prescribed direction in which the lead terminal extends. According to the semiconductor light-emitting device thus configured, it is possible to realize the shape where the area of the end surface formed at the tip end portion is smaller than the cross sectional area of the base portion, to thereby enjoy the above-described effects. Further, a step formed between the tip end portion and the base portion can serve as a receiver of solder excessively applied. Accordingly, soldering can be conducted more satisfactorily upon mounting of the semiconductor light-emitting device.

An electronic image pickup device according to the present invention includes any of the above-described semiconductor light-emitting devices. According to the electronic image pickup device thus configured, the above-described effects can be enjoyed in the electronic image pickup device.

When a reference plane of a rectangular shape is provided at a prescribed distance from the semiconductor light-emitting device, luminance at each corner of the reference plane irradiated with the light from the semiconductor light-emitting device is preferably not less than 50% of luminance at the center of the reference plane. According to the electronic image pickup device thus configured, directivity of the light emitted from the semiconductor light-emitting element can be controlled appropriately, so that a desired shooting condition that there is little difference in brightness over the reference plane can be realized.

As described above, according to the present invention, it is possible to provide a semiconductor light-emitting device excellent in heat radiation and capable of controlling directivity of light appropriately, a manufacturing method thereof, and an electronic image pickup device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a semiconductor light-emitting device according to a first embodiment of the present invention.

FIG. 2 is a plan view of the semiconductor light-emitting device in FIG. 1.

FIG. 3 is a cross sectional view taken along the line III-III in FIG. 1.

FIG. 4 is a cross sectional view schematically showing how the light is reflected by the inner wall of the resin portion.

FIGS. 5 and 6 are cross sectional views illustrating modifications of the shape defined by the inner wall.

FIG. 7 is a cross sectional view of a semiconductor light-emitting device according to a second embodiment of the present invention.

FIG. 8 is a cross sectional view of a semiconductor light-emitting device according to a third embodiment of the present invention.

FIG. 9 is a plan view of a semiconductor light-emitting device according to a fourth embodiment of the present invention.

FIG. 10 is a perspective view of a portable telephone equipped with a camera according to a fifth embodiment of the present invention.

FIG. 11 is a schematic diagram illustrating luminance over the reference plane that is irradiated with the light from the portable telephone equipped with a camera shown in FIG. 10.

FIG. 12 is a plan view of a semiconductor light-emitting device according to a sixth embodiment of the present invention.

FIG. 13 is a side view taken along the line XIII-XIII in FIG. 12.

FIG. 14 is a flowchart illustrating manufacturing steps of the semiconductor light-emitting device shown in FIG. 12.

FIG. 15 is a plan view illustrating the manufacturing step of the semiconductor light-emitting device shown in FIG. 12.

FIG. 16 is a cross sectional view illustrating a typical structure of a conventional semiconductor light-emitting device.

### DESCRIPTION OF THE PREFERRED EMBODIMENTS

Hereinafter, embodiments of the present invention will be described with reference to the drawings.

First Embodiment

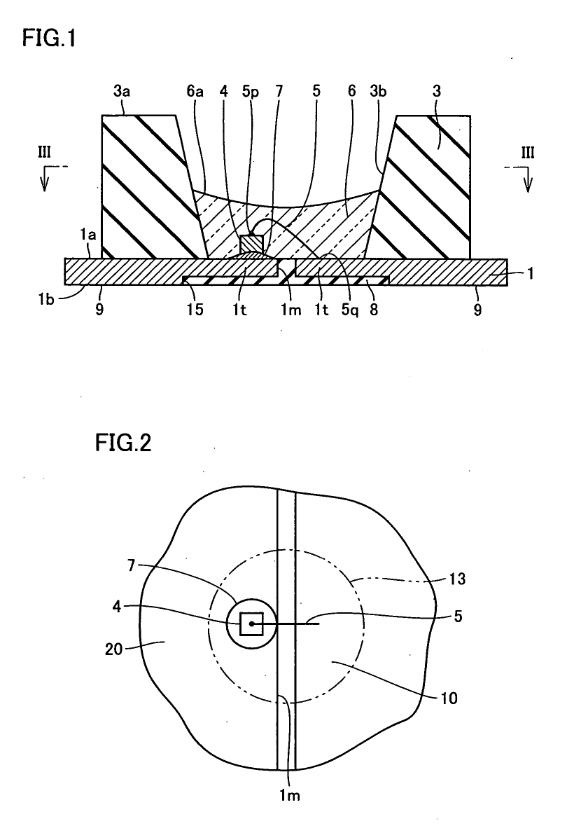

Referring to FIG. 1, the semiconductor light-emitting device includes a lead frame 1 having a main surface 1a that is formed into a prescribed pattern, a LED chip 4 that is provided on main surface 1a, an epoxy resin 6 that is provided on main surface 1a to cover LED chip 4, and a resin portion 3 that is provided around epoxy resin 6.

Lead frame 1 is in a plate shape that extends in one plane. Lead frame 1 is subjected to prescribed patterning to have a slip-shaped groove 1m formed to extend from main surface 1a to its opposite surface 1b.

Opposite surface 1b of lead frame 1 is provided with a groove 15 that is in communication with slit-shaped groove 1m. As such, the portion 1t of lead frame 1 where slit-shaped groove 1m is formed is made thinner than the other portion.

FIG. 2 shows part of the structures formed on lead frame 1. Referring to FIGS. 1 and 2, two regions 10 and 20 are defined at main surface 1a. Region 10 is a region-inside the circle 13 delimited by the two-dotted line, and region 20 is a region outside the circle 13 extending along the periphery of region 10. Slit-shaped groove 1m is formed to pass the center of circle 13, to separate part of lead frame 1.

LED chip 4 is provided in region 10 of main surface 1a. LED chip 4 is provided via a silver (Ag) paste 7. An electrode (not shown) provided on the top surface of LED chip 4 is connected via a metal wire 5 to a portion of main surface 1a that is separated, by slit-shaped groove 1m, from the portion of main surface 1a where LED chip 4 is provided. That is, LED chip 4 is mechanically and electrically connected to main surface 1a via silver paste 7 and via metal wire 5.

One end 5p of metal wire 5 connected to the electrode of LED chip 4 is formed in a ball shape. The other end 5q of metal wire 5 connected to main surface 1a is formed in a line shape. That is, at the time of wire bonding for connecting metal wire 5 to a prescribed position, firstly ball bonding of the one end 5p of metal wire 5 to the electrode of LED chip 4 is conducted, which is followed by wedge bonding of the other end 5q of metal wire 5 to main surface 1a.

As light is emitted from LED chip 4, heat is also generated. The heat generated is transmitted to lead frame 1, and externally released therefrom. In the present embodiment, portions 1t of lead frame 1 are made thin, which can be processed to have slit-shaped groove 1m of a small groove width. On the other hand, the remaining portion of lead frame 1 is made thick, and thus, efficient heat radiation by lead frame 1 becomes possible.

For such efficient heat radiation from lead frame 1, lead frame 1 is formed of a metal having heat conductivity of not smaller than 300 W/mK and not greater than 400 W/mK. If the heat conductivity of the metal forming lead frame 1 is smaller than 300 W/mK, the effect of releasing heat by lead frame 1 will be insufficient. If it is greater than 400 W/mK, heat generated upon mounting of lead frame 1 may be transmitted to LED chip 4, leading to degradation in reliability of LED chip 4.

Specifically, lead frame 1 is formed of an alloy having copper (Cu) as its main component to which a metal such as iron (Fe), zinc (Ze), nickel (Ni), chrome (Cr), silicon (Si), tin (Sn), lead (Pb), or silver (Ag) is added as appropriate. Reducing the amount of the metal added to copper can increase the heat conductivity of the alloy forming lead frame 1.

In the present embodiment, lead frame 1 is unfolded. Thus, when selecting a material for lead frame 1, it is unnecessary to take account of bendability of the material. This offers a wide selection of materials to choose the material for lead frame 1 therefrom. It is also unnecessary to concern about breaking or cracking that might otherwise occur upon bending of lead frame 1.

Lead frame 1 is insert-molded in a resin, so that resin portion 3 is provided on main surface 1a at region 20. The resin also forms a resin portion 8 on opposite surface 1b of lead frame 1. Resin portion 8 is provided to fill in slit-shaped groove 1m and groove 15. Resin portions 3 and 8 serve to keep the shape of lead frame 1 having been formed into a prescribed pattern. Particularly, in the present embodiment, resin portion 8 covers the wide area of opposite surface 1b of lead frame 1. This increases the adhesion strength between lead frame 1 and resin portion 8, and accordingly, reliability of the semiconductor light-emitting device can be increased. Terminal portions 9 for connecting the semiconductor light-emitting device to the mounting board are provided on opposite surface 1b side of lead frame 1, on both sides of resin portion 8.

Terminal portions 9 on the respective sides of resin portion 8 are separated from each other by resin portion 8 being an insulator. A such, upon soldering terminal portions 9 to the mounting board, occurrence of short circuiting between the anode and the cathode or between LED chips can be prevented.

Resin portion 3 has a top surface 3a that extends in a plane approximately parallel to main surface 1a, and an inner wall 3 that surrounds region 10 of main surface 1a where LED chip 4 is provided and extends in a direction away from main surface 1a. Inner wall 3b is in communication with main surface 1a and top surface 3a. Inner wall 3b of resin portion 3 functions as a reflecting surface for reflecting the light emitted from LED chip 4.

Resin portions 3 and 8 are formed of a white resin having a high reflectivity, to efficiently reflect the light from LED chip 4 with resin portion 3. Further, resin portions 3 and 8 are formed of a resin excellent in heat resistance, taking account of a reflow step upon manufacturing. Specifically, a liquid crystal polymer, a polyamide-based resin or the like satisfying the both conditions is preferably used, although other resins and ceramics may be used as the material for resin portions 3 and 8. Inner wall 3b may have its surface plated to reflect the light emitted from LED chip 4 more efficiently.

LED chip 4 and metal wire 5 are located in the depression that is formed with inner wall 3b of resin portion 3 and main surface 1a. Epoxy resin 6 is provided in the depression to cover LED chip 4 and metal wire 5. Epoxy resin 6 serves to protect LED chip 4 and metal wire 5 from external physical and/or electrical contacts. Epoxy resin 6 has a top surface 6a that is slightly depressed from the inner wall 3b side toward the center. Epoxy resin 6 is formed such that the distance from main surface 1a to top surface 6a is shorter than the distance from main surface 1a to top surface 3a of resin portion 3. As such, inner wall 3b extends even above top surface 6a of epoxy resin 6 in a direction toward top surface 3a.

Epoxy resin 6 is formed of a material having a reflectivity that is smaller than that of resin portion 3 with respect to the light emitted from LED chip 4. Specifically, a transparent or opalescent resin is used, which is injected into a mold by a potting system. Alternatively, transfer molding, injection molding or the like may be employed to provide epoxy resin 6. In such a case, epoxy resin 6 can be formed into an arbitrary shape (e.g., a lens shape).

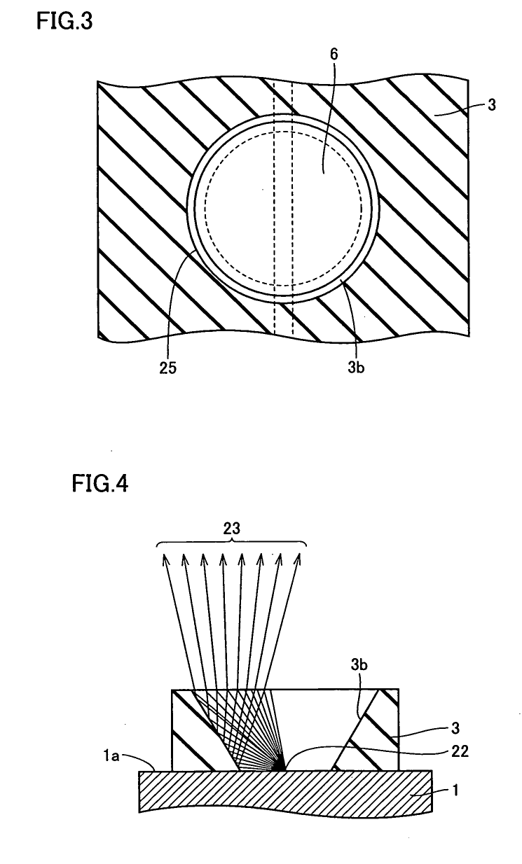

Referring to FIGS. 1 and 3, the shape 25 defined by inner wall 3b in a plane parallel to main surface 1a is in the form of a circle. Resin portion 3 is formed such that the area of shape 25 defined by inner wall 3b increases as the distance from main surface 1a increases. That is, assuming a circular cone having its cone point located downward, inner wall 3b has a shape corresponding to the sidewall of such a circular cone extending from its bottom surface-toward the cone point.

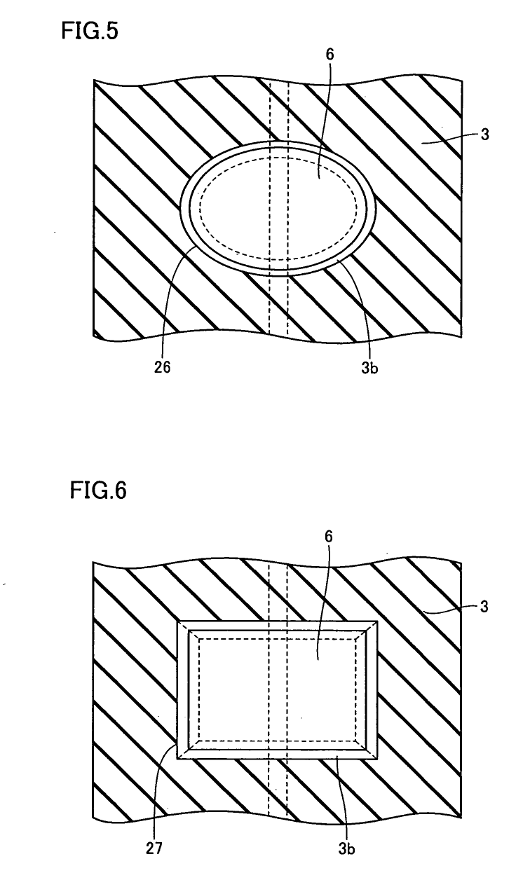

Referring to FIG. 4, assuming that a light source 22 is provided on main surface 1a, the light emitted from light source 22 travels in, all directions. In a semiconductor light-emitting device, it is important to control directivity of the light emitted from light source 22 appropriately to obtain the light of high luminance in a prescribed direction. Since resin portion 3 is formed such that the area of the shape defined by inner wall 3b increases with an increase of the distance from main surface 1a, the light traveling from the light source in the direction closer to main surface 1a can be reflected by inner wall 3b to a prescribed direction. Thus, the light emitted from the light source can be taken out to the front of the semiconductor light-emitting device, i.e., to the direction indicated by arrows 23. In addition, since the shape defined by inner wall 3b in a plane parallel to main surface 1a is in a circular shape, the directivity of the light can readily be controlled by adjusting the tilt of inner wall 3b.

In the present embodiment, referring to FIG. 1, the light emitted from LED chip 4 is reflected by inner wall 3b in a prescribed direction, transmitted by epoxy resin 6, and emitted from its top surface 6a to the outside. The traveling direction of the light changes due to refraction at top surface 6a. However, since inner wall 3b serving as the reflecting surface is present also above top surface 6a, inner wall 3b can reflect the light again, to make it emitted to the front of the semiconductor light-emitting device.

FIGS. 5 and 6 are cross sectional views corresponding to the cross section shown in FIG. 3.

Referring to FIG. 5, resin portion 3 may be formed such that the shape 26 defined by inner wall 3b in a plane parallel to main surface 1a forms an ellipse. Alternatively, referring to FIG. 6, resin portion 3 may be formed such that the shape 27 defined by inner wall 3b in a plane parallel to main surface 1a forms a rectangle. In either case, the light-emitting area of the light generated from the semiconductor laser-emitting device can be made large. As such, the shape of resin portion 3 to be provided may be changed as appropriate depending on an intended purpose of electronic equipment or the like to which the semiconductor light-emitting device is mounted.

The semiconductor light-emitting device according to the first embodiment of the present invention includes: lead frame 1 having main surface 1a in which region 10 as the first region and region 20 as the second region extending along the periphery of region 10 are defined; LED chip 4 as the semiconductor light-emitting element that is provided at region 10; epoxy resin 6 as the first resin member that is provided at region 10 to completely cover LED chip 4; and resin portion 3 as the second resin member that is provided at region 20 to surround LED chip 4.

Epoxy resin 6 has a first reflectivity with respect to the light emitted from LED chip 4. Resin portion 3 has a second reflectivity greater than the first reflectivity with respect to the light emitted from LED chip 4. Epoxy resin 6 includes top surface 6a as the first top surface. Resin portion 3 includes top surface 3a as the second top surface that is provided in a position where the distance from main surface 1a is greater than the distance from main surface 1a to top surface 6a, and inner wall 3b that is provided on the side where LED chip 4 is located and extends in a direction away from main surface 1a to reach top surface 3a.

The semiconductor light-emitting device further includes metal wire 5 as the metallic wire having one end 5p connected to LED chip 4 and the other end 5q connected to main surface 1a. Epoxy resin 6 is provided to completely cover metal wire 5.

Lead frame 1 includes portions 1t separated by slit-shaped groove 1m. Portions 1t are made thinner than the other portion of lead frame 1.

Lead frame 1 is formed in a plate shape that extends in one plane. Lead frame 1 includes groove 15 as the first depression that is formed at opposite surface 1b with respect to main surface 1a and filled with resin portion 8 as the resin. Terminals 9 are provided on opposite surface 1b, which are located on the respective sides of groove 15 and electrically connected to the mounting board.

Resin portion 3 is formed such that the area of the shape defined by inner wall 3b in a plane parallel to main surface 1a increases as the distance from main surface 1a increases. The shape defined by inner wall 3b in a plane parallel to main surface 1a may be any of circle, ellipse, and polygon.

According to the semiconductor light-emitting device configured as above, inner wall 3b for reflecting the light emitted from LED chip 4 extends even above top surface 6a. Further, top surface 6a of epoxy resin 6 is provided at a relatively low level, so that it is possible to suppress attenuation of the light as it transmits epoxy resin 6. Still further, since the height of lead frame 1, formed in a plate shape, is kept low, resin portion 3 can be increased in height, and inner wall 3b can be made to extend to a higher level for reflecting the light emitted from LED chip 4. Accordingly, it is possible to appropriately control directivity of the light emitted from LED chip 4 and to take out high-luminance light from the semiconductor light-emitting device.

Second Embodiment

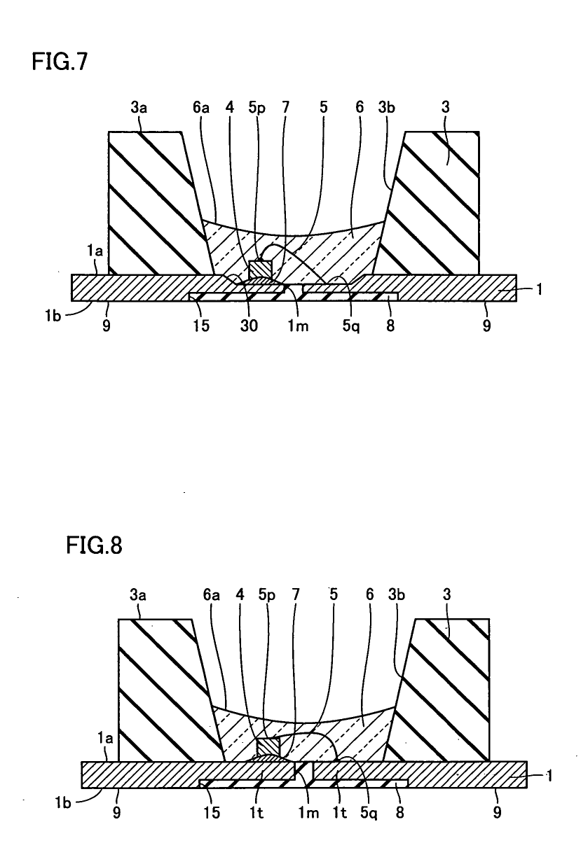

Referring to FIG. 7, the semiconductor light-emitting device of the second embodiment differs from the semiconductor light-emitting device of the first embodiment in the shape of lead frame 1. In the following, description of the common structures is not repeated.

A depression 30 is formed at main surface 1a of lead frame 1, in region 10 (see FIG. 2). LED chip 4 is provided on the bottom surface of depression 30 via silver paste 7. Metal wire 5 extending from the top surface of LED chip 4 has its other end 5q connected to the bottom surface of depression 30. The sidewall of depression 30 has a tilt such that the area of the opening of depression 30 at main surface 1a is greater than the area of the bottom surface of depression 30.

Epoxy resin 6 is provided to cover LED chip 4 and metal wire 5. In the present embodiment, top surface 6a of epoxy resin 6 is formed at a relatively low level compared to the first embodiment, since LED chip 4 is provided at a relatively low level.

In the semiconductor light-emitting device according to the second embodiment, lead frame 1 includes depression 30 as the second depression that is formed at region 10, and LED chip 4 is provided in depression 30.

According to the semiconductor light-emitting device thus configured, effects similar to those described in the first embodiment can be enjoyed. Further, the sidewall of depression 30 serves as the reflecting surface that reflects the light emitted from LED chip 4. Since LED chip 4 is provided on the bottom surface of depression 30, the distance of inner wall 3b extending from top surface 6a to top surface 3a can be increased without changing the height of resin portion 3. Accordingly, control of the directivity of the light emitted from LED chip 4 is further facilitated.

Third Embodiment

Referring to FIG. 8, the semiconductor light-emitting device according to the third embodiment differs from the semiconductor light-emitting device of the first embodiment in the manner of wire bonding metal wire 5 to main surface 1a and to the top surface of LED chip 4. In the following, description of the common structures is not repeated.

One end 5p of metal wire 5 connected to the electrode of LED chip 4 is formed in a line shape, and the other end 5q of metal wire 5 connected to main surface 1a is formed in a ball shape. Wire bonding for connecting metal wire 5 to a prescribed position is conducted by ball bonding the other end 5q of metal wire 5 to main surface 1a and then wedge bonding the end 5p of metal wire 5 to the electrode of LED chip 4. As such, the loop shape of metal wire 5 formed on the side of the top surface of LED chip 4 can be reduced in size.

Epoxy resin 6 is provided to cover LED chip 4 and metal wire 5. At this time, since the loop shape of metal wire 5 is made small in size, top surface 6a of epoxy resin 6 is formed at a lower level than in the case of the first embodiment.

In the present embodiment, the strength of connection between the wedge-bonded end 5p of metal wire 5 and the electrode of LED chip 4 is slightly decreased, and reliability required (such as resistance to reflow or resistance to heat cycle) may not be satisfied. In such a case, the connection can be enhanced by ball bonding an additional metal from above the wedge-bonded end 5p of metal wire 5. This ball bonding may be conducted from above the other end 5q of metal wire 5 having already been ball-bonded.

In the semiconductor light-emitting device according to the third embodiment of the present invention, one end 5p of metal wire 5 is formed in a line shape and the other end 5q of metal wire 5 is formed in a ball shape. The one end 5p is provided with a ball-shaped metal to sandwich metal wire 5 between the ball-shaped metal and LED chip 4.

According to the semiconductor light-emitting device thus configured, effects similar to those described in the first embodiment can be enjoyed. Further, since end 5p of metal wire 5 is wedge-bonded to the electrode of LED chip 4, the distance of inner wall 3b extending from top surface 6a to top surface 3a can be increased without changing the height of resin portion 3. Accordingly, control of the directivity of the light emitted from LED chip 4 can further be facilitated.

Fourth Embodiment

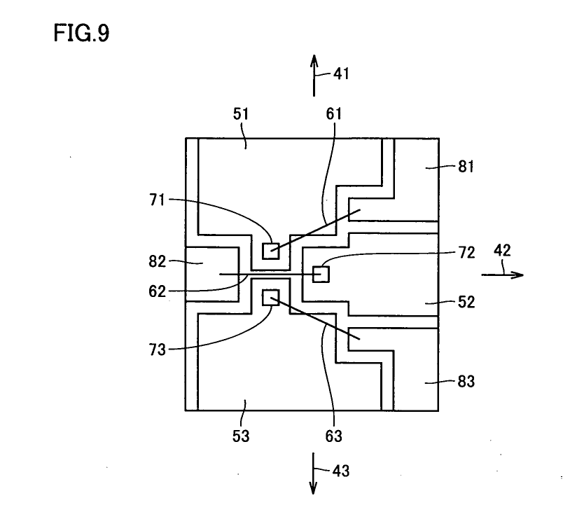

Referring to FIG. 9, in the semiconductor light-emitting device according to the fourth embodiment, LED chips 71, 72 and 73 are mounted to main surfaces of lead frames 51, 52 and 53, respectively, in the manner described in any of the first through third embodiments.

LED chips 71, 72 and 73 are those emitting light of blue, red and green, respectively. LED chips 71, 72 and 73 are provided close to each other, corresponding approximately to the apexes of a triangle. Portions of lead frames 51, 52 and 53 where LED chips 71, 72 and 73 are provided, respectively, are spaced apart from each other by slit-shaped grooves. Such close arrangement of the LED chips emitting the different colors results in a full-color semiconductor light-emitting device.

Lead frames 51, 52 and 53 extend in different directions (as shown by arrows 41, 42 and 43) from the respective portions where LED chips 71, 72 and 73 are provided. Lead frames 51, 52 and 53 are formed such that the areas of the main surfaces of lead frames 51 and 53 are each greater than the area of the main surface of lead frame 52.

A lead frame 81 is provided between lead frames 51 and 52, a lead frame 83 is provided between lead frames 52 and 53, and a lead frame 82 is provided between lead frames 53 and 51. Metal wires 61, 62 and 63 electrically connect lead frame 81 and LED chip 71, lead frame 82 and LED chip 72, and lead frame 83 and LED chip 73, respectively.

The semiconductor light-emitting device according to the fourth embodiment includes LED chips 72, 71 and 73 as the three semiconductor light-emitting elements emitting light of red, blue and green, respectively, and three lead frames 52, 51 and 53 spaced apart from each other to which LED chips 72, 71 and 73 are respectively provided. Lead frames 52, 51 and 53 extend in different directions from each other.

The areas of the main surfaces of lead frames 51 and 53, to which LED chips 71 and 73 emitting light of blue and green, respectively, are provided, are each greater than the area of the main surface of lead frame 52 to which LED chip 72 emitting red light is provided.

According to the semiconductor light-emitting device thus configured, even the full-color semiconductor light-emitting device can enjoy the effects as in the first through third embodiments. Particularly, as described in the first embodiment, the portions of lead frames 51, 52 and 53 where slit-shaped grooves are to be formed are made thin, so that they can be processed to have the slit-shaped grooves of narrow widths. As such, LED chips 71, 72 and 73 can be arranged closer to each other, and accordingly, efficiency of color mixture of the semiconductor light-emitting device can be improved.

Further, lead frames 51, 52 and 53 extend in different directions from each other. As such, the heat generated in LED chips 71, 72 and 73 can be dispersed, and efficient heat radiation becomes possible. Still further, taking account of the great amounts of heat generated by LED chips 73 and 71 emitting light of green and blue, the areas of the main surfaces of lead frames 53. and 51 to which LED chips 73 and 71 are mounted, respectively, are each made greater than the area of the main surface of lead frame 52 to which LED chip 72 emitting red light is mounted. Accordingly, the heat generated by LED chips 71, 72 and 73 can be released uniformly via lead frames 51, 52 and 53.

The present invention can effectively be applied particularly to a full-color semiconductor light-emitting device provided with a plurality of LED chips, where a great amount-of heat is generated from the LED chips. According to the present invention, the angle of beam spread can readily be narrowed in accordance with the shape of inner wall 3b being provided. As such, even in the full-color semiconductor light-emitting device, luminance of the light taken out can be increased without impairing the efficiency of color mixture. Although a lens may be provided to adjust the angle of beam spread, it would be very difficult to improve the color mixture efficiency at the same time. In addition, provision of the lens would adversely increase the height of the semiconductor light-emitting device as a product.

Fifth Embodiment

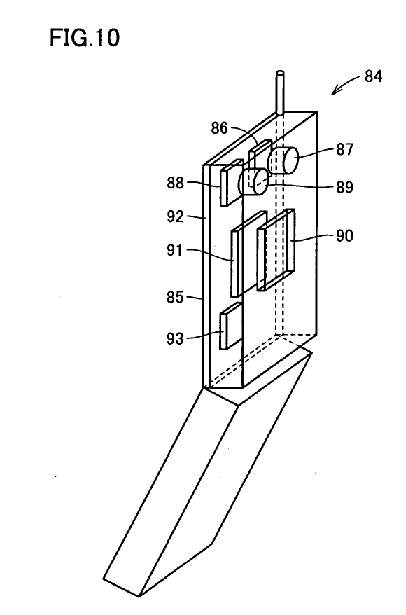

Referring to FIG. 10, a portable telephone 84 equipped with a camera includes a semiconductor light-emitting device 86 that corresponds to the semiconductor light-emitting device described in the fourth embodiment.

A liquid crystal display screen 90, a window 89 for a CCD (charge coupled device), and a window 87 for a light-emitting device are formed at a front surface of a casing 85. A mounting board 92 is provided in casing 85. A liquid crystal 91, a CCD 88, and semiconductor light-emitting device 86 are provided on mounting board 92, opposite to liquid crystal display screen 90, CCD window 89, and light-emitting device window 87, respectively. In addition to liquid crystal 91, CCD 88 and semiconductor light-emitting device 86, an electronic component 93 such as an IC chip is provided on mounting board 92.

In portable telephone 84 equipped with a camera of the present embodiment, semiconductor light-emitting device 86 is used as an auxiliary light source, to enable photographing of a subject in a dark place. Specifically, the three LED chips provided in semiconductor light-emitting device 86 emit light of blue, red and green, to thereby irradiate the subject with light of white color. As such, it is possible to take a picture of the brightly illuminated subject, and take it into CCD 88 as electronic data.

In portable telephone 84 equipped with a camera, semiconductor light-emitting device 86 is set such that a subject is irradiated with light of uniform brightness.

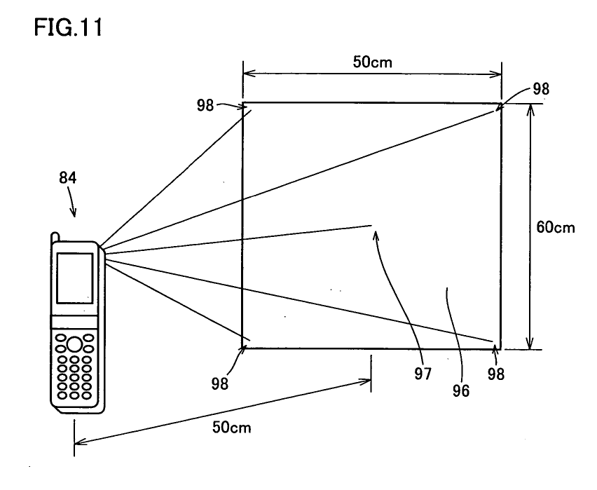

Referring to FIG. 11, a reference plane of a prescribed size is provided at a prescribed distance from the light source of portable telephone 84 equipped with a camera. This reference plane represents the range of a subject taken by portable telephone 84 equipped with a camera. In the present embodiment, the reference plane 96 having a size of 60 cm in a vertical direction and 50 cm in a horizontal direction is provided at a distance of 50 cm from the light source of portable telephone 84 equipped with a camera.

Semiconductor light-emitting device 86 of portable telephone 84 equipped with a camera is set such that, when light is emitted from portable telephone 84 equipped with a camera toward the center 97 of reference plane 96, luminance measured at each corner 98 of reference plane 96 is not lower than 50% of luminance measured at the center 97. For example, when the luminance measured at center 97 is 30 lux, the luminance of not lower than 15 lux is measured at each corner 98.

Portable telephone 84 equipped with a camera as the electronic image pickup device according to the fifth embodiment of the present invention includes semiconductor light-emitting device 86. When reference plane 96 of a rectangular shape is provided at a prescribed distance from semiconductor light-emitting device 86, luminance at each corner of reference plane 96 irradiated with the light from semiconductor light-emitting device 86 is not lower than 50% of luminance at the center of reference plane 96.

According to the portable telephone 84 equipped with a camera thus configured, directivity of the light emitted from semiconductor light-emitting device 86 can readily be controlled, by virtue of the effects described in the fourth embodiment. Accordingly, it is readily possible to realize a desired shooting condition that there is little difference in brightness over the reference plane in which the subject is taken.

Sixth Embodiment

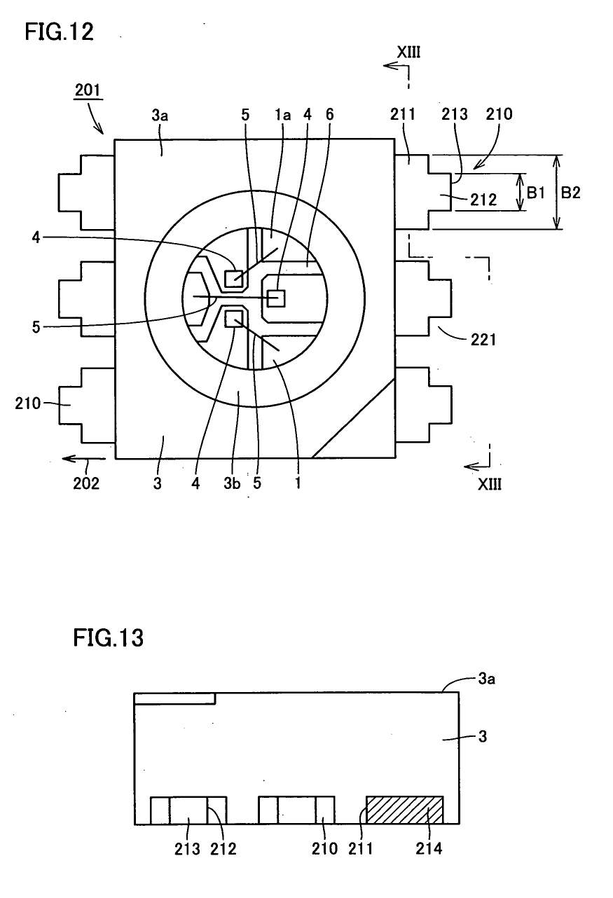

Referring to FIGS. 12 and 13, of which FIG. 13 is partly in cross section, the semiconductor light-emitting device 201 according to the sixth embodiment has three LED chips 4 mounted on main surface 1a of lead frame 1, as in the case of the semiconductor light-emitting device of the fourth embodiment.

Lead frame 1 is provided with a plurality of lead terminals 210 projecting from the periphery of main surface 1a. Lead terminals 210 are exposed from resin portion 3, and each extend from a position, spaced apart from each other, in a direction away from the periphery of main surface 1a (as shown by an arrow 202). Lead terminal 210 consists of a base portion 211 that is formed at a position relatively close to the periphery of main surface 1a, and a tip end portion 212 that is formed at a position relatively far from the periphery of main surface 1a and has an end surface 213 at the tip end of projecting lead terminal 210. End surface 213 extends in a plane orthogonal to the direction shown by arrow 202 in which lead terminal 210 extends.

Base portion 211 has a width B2, and tip end portion 212 and end surface 213 have a width B1 that is narrower than width B2. That is, lead terminal 210 is formed to be thinner at the tip end side far from the periphery of main surface 1a than at the root side close to the periphery of main surface 1a. The area of end surface 213 is made smaller than the area of the cross section (shown as the hatched portion 214 in FIG. 13) that is obtained when base portion 211 is cut in a plane orthogonal to the direction shown by arrow 202. A stepped portion 221 is formed between base portion 211 and tip end portion 212.

A manufacturing method of the semiconductor light-emitting device shown in FIG. 12 is now described.

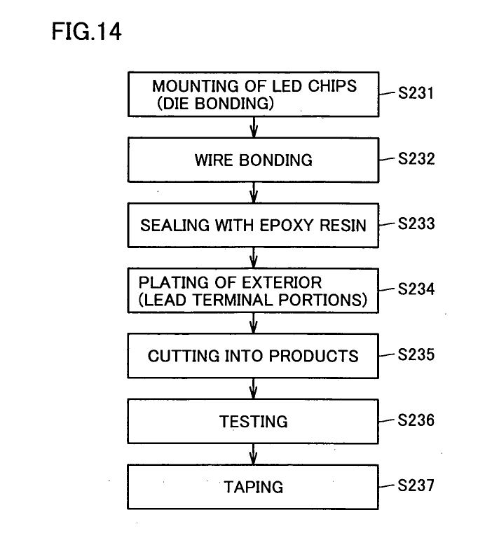

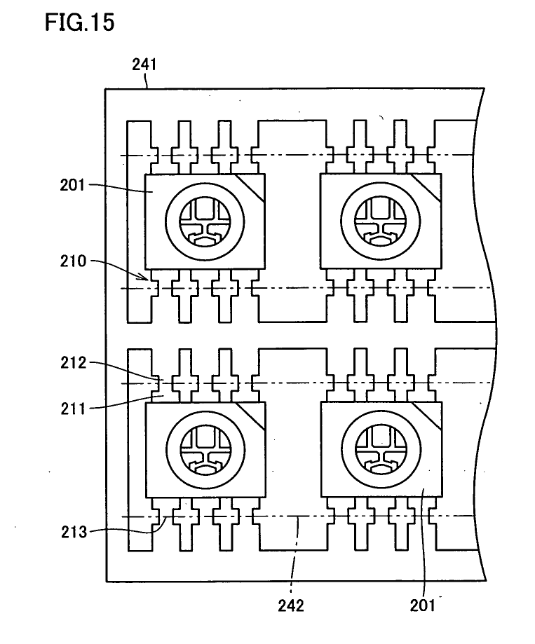

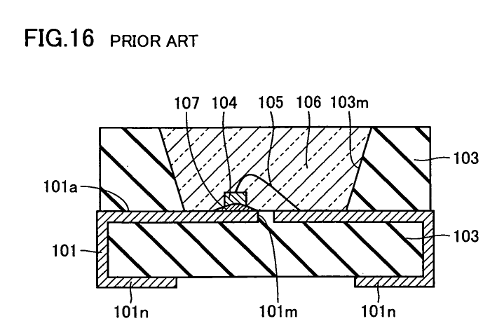

Referring to FIGS. 14 and 15, firstly, a lead frame base member 241 is prepared where a lead frame having been patterned into a prescribed shape is insert-molded, for example, in a resin portion 3, and a plurality of LED chips 4 are mounted to lead frame base member 241 (S231). Next, wire bonding is conducted (S232) to connect electrodes of the mounted LED chips 4 to a surface of lead frame base member 241 by metal wires, which are then sealed with an epoxy resin 6 (S233).

Thereafter, lead terminals 210 are subjected to plating using, e.g., tin (Sn) and bismuth (Bi), or tin (Sn) and lead (Pb) (solder plating) (S234). At the end of this step, lead frame base member 241 having a plurality of semiconductor light-emitting devices 201 arranged in a matrix, as shown in FIG. 15, is completed.

Next, a pressing machine is used to cut lead frame base member 241 along a plurality of tip end portions 212 arranged in a straight line (i.e., along the two-dotted line 242) (S235). As such, the plurality of semiconductor light-emitting devices 201 are cut out of lead frame base member 241, and end surfaces 213 corresponding to the cut surfaces by the mold are formed at respective tip end portions 212. Thereafter, semiconductor light-emitting devices 201 are subjected to a testing step (S236), and then a taping step (S237) is conducted to have semiconductor light-emitting devices 201 ready for shipment.

In semiconductor light-emitting device 201 according to the sixth embodiment, lead frame 1 includes lead terminals 210 each projecting from the periphery of main surface 1a and extending in a prescribed direction. Lead terminal 210 has tip end portion 212 having end surface 213 formed at the tip end extending in the prescribed direction, and base portion 211 located between the periphery of main surface 1a and tip end portion 212. Lead terminal 210 is formed such that the area of end surface 213 is smaller than the cross sectional area of base portion 211 in a plane parallel to end surface 213. Lead terminal 210 has width B2 as the first width at base portion 211, and width B1 as the second width smaller than width B2 at tip end portion 212. End surface 213 formed at tip end portion 212 corresponds to a cut surface formed by a prescribed cutting tool.

The manufacturing method of semiconductor light-emitting device 201 according to the sixth embodiment includes the step of preparing lead frame base member 241 having a plurality of semiconductor light-emitting devices 201 formed thereon, and the step of cutting the plurality of semiconductor light-emitting devices 201 out of lead frame base member 241 by cutting lead frame base member 241 at tip end portions 212.

According to the semiconductor light-emitting device and the manufacturing method thereof as described above, in the step S235 shown in FIG. 14, end surface 213 is formed as the cut surface by a mold. Thus, the metal such as copper (Cu) as the material of lead frame 1 will be exposed and oxidized at end surface 213, leading to degradation of wettability with respect to solder. However, in the present embodiment, lead terminal 210 is formed to make the area of end surface 213 relatively small, so that such an adverse effect can be restricted to a minimum possible level. Further, stepped portion 221 formed between base portion 211 and tip end portion 212 functions as a space where excessively applied solder can be received, and thus, occurrence of a solder ball or the like can be suppressed. For the reasons as described above, according to the present embodiment, soldering can satisfactorily be conducted for lead terminals 210 when mounting semiconductor light-emitting device 201 to a printed circuit board or the like.

Further, compared to the case where lead terminal 210 is formed with a uniform width B2 from base portion 211 to tip end portion 212, the force required for cutting in the step S235 can be reduced. This enables simplification of the mold and downsizing of the pressing machine. A great number of semiconductor light-emitting devices 201 can be cut out simultaneously with the same capability of the pressing machine. Accordingly, it is possible to improve the production capacity of semiconductor light-emitting devices 201.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor light-emitting device, comprising:
a lead frame having a main surface in which a first region and a second region extending along the periphery of said first region are defined;
a semiconductor light-emitting element provided at said first region;
a first resin member having a first reflectivity with respect to light emitted from said semiconductor light-emitting element and provided at said first region to completely cover said semiconductor light-emitting element; and
a second resin member having a second reflectivity greater than said first reflectivity with respect to the light emitted from said semiconductor light-emitting element and provided at said second region to surround said semiconductor light-emitting element; wherein
said first resin member includes a first top surface, and
said second resin member includes a second top surface that is provided at a position where a distance from said main surface is greater than a distance from said main surface to said first top surface, and an inner wall that is provided on a side where said semiconductor light-emitting element is located and extends in a direction away from said main surface to reach said second top surface.

2. The semiconductor light-emitting device according to claim 1, further comprising a metallic wire having one end connected to said semiconductor light-emitting element and another end connected to said main surface, and said first resin member is provided to completely cover said metallic wire.

3. The semiconductor light-emitting device according to claim 2, wherein said one end is formed in a line shape, and said anther end is formed in a ball shape.

4. The semiconductor light-emitting device according to claim 2, wherein said one end is provided with a ball-shaped metal to sandwich said metallic wire between the ball-shaped metal and said semiconductor light-emitting element.

5. The semiconductor light-emitting device according to claim 1, comprising three said semiconductor light-emitting elements emitting light of red, blue and green, respectively, and three said lead frames spaced apart from each other and provided with respective said three semiconductor light-emitting elements, said lead frames extending in different directions from each other.

6. The semiconductor light-emitting device according to claim 5, wherein areas of said main surfaces of said lead frames provided with said semiconductor light-emitting elements emitting the light of blue and green, respectively, are each greater than an area of said main surface of said lead frame provided with said semiconductor light-emitting element emitting the light of red.

7. The semiconductor light-emitting device according to claim 1, wherein said lead frame includes portions separated by a slit-shaped groove, and said portions are formed thinner than the other portion of said lead frame.

8. The semiconductor light-emitting device according to claim 1, wherein said lead frame is formed in a plate shape extending in one plane.

9. The semiconductor light-emitting device according to claim 8, wherein said lead frame includes a first depression that is formed at an opposite surface with respect to said main surface and filled with a resin, and terminal portions to be electrically connected to a mounting board are provided on said opposite surface, on respective sides of said first depression.

10. The semiconductor light-emitting device according to claim 1, wherein said lead frame includes a second depression formed at said first region, and said semiconductor light-emitting element is provided in said second depression.

11. The semiconductor light-emitting device according to claim 1, wherein said lead frame is formed of a metal having a heat conductivity of not lower than 300 W/mK and not greater than 400 W/mK.

12. The semiconductor light-emitting device according to claim 1, wherein said second resin member is formed such that an area of a shape defined by said inner wall in a plane parallel to said main surface increases with an increase of a distance from said main surface.

13. The semiconductor light-emitting device according to claim 1, wherein a shape defined by said inner wall in a plane parallel to said main surface is one of circle, ellipse and polygon.

14. The semiconductor light-emitting device according to claim 1, wherein
said lead frame includes a lead terminal projecting from the periphery of said main surface and extending in a prescribed direction, and said lead terminal has a tip end portion having an end surface formed at a tip end extending in said prescribed direction, and a base portion located between the periphery of said main surface and said tip end portion, and
said lead terminal is formed such that an area of said end surface is smaller than a cross sectional area of said base portion in a plane parallel to said end surface.

15. The semiconductor light-emitting device according to claim 14, wherein said lead terminal has a first width at said base portion and a second width smaller than said first width at said tip end portion.

16. The semiconductor light-emitting device according to claim 14, wherein said end surface corresponds to a cut surface formed by a prescribed cutting tool.

17. A manufacturing method of the semiconductor light-emitting device recited in claim 16, comprising the steps of:
preparing a lead frame base member having a plurality of said semiconductor light-emitting devices formed thereon; and
cutting the plurality of said semiconductor light-emitting devices out of said lead frame base member by cutting said lead frame base member at said tip end portions.

18. An electronic image pickup device, comprising the semiconductor light-emitting device recited in claim 1.

19. The electronic image pickup device according to claim 18, wherein when a reference plane of a rectangular shape is provided at a prescribed distance from said semiconductor light-emitting device, luminance at each corner of said reference plane irradiated with the light from said semiconductor light-emitting device is not less than 50% of luminance at the center of said reference plane.
